(19) United States
(12) Patent Application Publication
(10) Pub. No.: US 2025/0318443 A1
(43) Pub. Date: Oct. 9, 2025

(54) JOSEPHSON JUNCTION DEVICE

(71) Applicant: ELECTRONICS AND TELECOMMUNICATIONS RESEARCH INSTITUTE, Daejeon (KR)

(72) Inventors: Woo Jung LEE, Daejeon (KR); Yong-Duck CHUNG, Daejeon (KR); DAEHYUNG CHO, Daejeon (KR); Tae-Ha HWANG, Daejeon (KR)

(21) Appl. No.: 19/081,482

(22) Filed: Mar. 17, 2025

(30) Foreign Application Priority Data
Apr. 5, 2024 (KR) 10-2024-0046640
Feb. 14, 2025 (KR) 10-2025-0019668

(51) Int. Cl. H10N 60/12

(52) U.S. Cl. CPC H10N 60/12

(57) ABSTRACT

Disclosed is a Josephson junction device including a first superconducting electrode and a second superconducting electrode spaced apart from the first superconducting electrode. Each of the first superconducting electrode and the second superconducting electrode includes CuₓBi₂Se₃, and x is greater than or equal to 0.05 and less than or equal to 0.5.

### CROSS-REFERENCE TO RELATED APPLICATIONS

This application claims priority under 35 U.S.C. § 119 to Korean Patent Application Nos. 10-2024-0046640 and 10-2025-0019668 filed on Apr. 5, 2024 and Feb. 14, 2025, respectively, in the Korean Intellectual Property Office, the disclosures of which are incorporated by reference herein in their entireties.

### BACKGROUND

### 1. Field of the Invention

Embodiments of the present disclosure described herein relate to a quantum computing device, and more particularly, relate to a Josephson junction device.

### 2. Description of Related Art

A quantum computer is defined as a computer that uses a qubit as a basic unit of information processing and is capable of very rapidly performing operations by utilizing quantum superposition and entanglement states when compared to a classical computer. There are several ways to implement the qubit in the quantum computer, including superconductor technology, ion trap, semiconductor quantum dot, topological qubit, solid defect, and photon, and the technologies capable of performing actual quantum operations are summarized into three technologies: superconductor, ion trap, and semiconductor quantum dot. Among them, the qubit technology used in quantum computing released by IBM and Google uses a superconductor-based transmon qubit, which can be said to be the most technologically mature field. The superconductor-based transmon qubit connects an LC resonant circuit to a Josephson junction device serving as a variable inductor and performs quantum operations by inputting microwaves corresponding to the resonant frequency of the circuit and utilizing the quantized energy levels as 0 and 1 states.

A typical Josephson junction structure is constituted by a superconductor/an insulator/a superconductor, and Cooper pairs formed in one superconductor tunnel into the other superconductor to generate a supercurrent. A transmon qubit currently used in quantum computing forms a Josephson junction having an Al/AlOx/Al structure by using Al layers as superconductors and an AlOx layer as an insulator. The Al material has a long coherence length, and the AlOx layer serving as an insulator is formed to be a very thin film having a thickness of 1 nm to 2 nm. However, the critical magnetic field is very low. Recent research results have shown that defects existing in the AlOx layer having a thickness of 1 nm to 2 nm affect the characteristics of the Josephson junction and are correlated with the coherence time of the qubit. That is, it means that the interface characteristics of the Josephson junction play an important role in the quality of the qubit.

### SUMMARY

Embodiments of the present disclosure provide a Josephson junction device for increasing an operating temperature of a superconducting transmon qubit and coherence time.

According to an embodiment, a Josephson junction device includes a first superconducting electrode and a second superconducting electrode spaced apart from the first superconducting electrode. Each of the first superconducting electrode and the second superconducting electrode includes CuₓBi₂Se₃, and x is greater than or equal to 0.05 and less than or equal to 0.5 (0.05≤x≤0.5).

The Josephson junction device may further include a topological insulator provided between the first superconducting electrode and the second superconducting electrode.

The topological insulator may include Bi₂Se₃. The first superconducting electrode may include a plurality of first superconducting electrodes, and the second superconducting electrode may include a plurality of second superconducting electrodes. The plurality of first superconducting electrodes may include a first lower electrode and a first upper electrode over the first lower electrode. The plurality of second superconducting electrodes may include a second lower electrode between the first lower electrode and the first upper electrode and a second upper electrode over the first upper electrode.

The topological insulator may include a plurality of topological insulators, and the plurality of topological insulators may include a lower topological insulator between the first lower electrode and the second lower electrode and an upper topological insulator between the first upper electrode and the second upper electrode.

The Josephson junction device may further include a device insulator between the second lower electrode and the first upper electrode.

The device insulator may include Cu_{y}Bi₂Se₃, and y may be greater than 0.5 and less than or equal to 1 (0.5<y≤1).

The Josephson junction device may further include a lower buffer layer between the first superconducting electrode and the topological insulator and an upper buffer layer provided between the topological insulator and the second superconducting electrode.

The lower buffer layer may include a first lower buffer layer, a second lower buffer layer between the first lower buffer layer and the topological insulator, a third lower buffer layer between the second lower buffer layer and the topological insulator, and lower nano particles between the third lower buffer layer and the topological insulator.

The upper buffer layer may include a first upper buffer layer, a second upper buffer layer between the first upper buffer layer and the second superconducting electrode, a third upper buffer layer between the second upper buffer layer and the second superconducting electrode, and upper nano particles between the first upper buffer layer and the topological insulator.

According to an embodiment, a Josephson junction device includes a first lower electrode, a lower topological insulator provided on the first lower electrode, a second lower electrode provided on the lower topological insulator, a device insulator provided on the second lower electrode, a first upper electrode provided on the device insulator, an upper topological insulator provided on the first upper electrode, and a second upper electrode provided on the upper topological insulator.

Each of the first lower electrode, the second lower electrode, the first upper electrode, and the second upper electrode may include CuₓBi₂Se₃, and x may be greater than or equal to 0.05 and less than or equal to 0.5 (0.05≤x≤0.5).

The device insulator may include Cu_{y}Bi₂Se₃, and y may be greater than 0.5 and less than or equal to 1 (0.5<y≤1).

Each of the lower topological insulator and the upper topological insulator may include Bi₂Se₃.

Each of the lower topological insulator and the upper topological insulator may include Bi₂Te₃, BiS_{b}, Sb₂Te₃, or TiBiSe₂.

According to an embodiment, a Josephson junction device includes a first superconducting electrode, a topological insulator provided on the first superconducting electrode, a second superconducting electrode provided on the topological insulator, and a lower buffer layer provided between the first superconducting electrode and the topological insulator.

The lower buffer layer may include a first lower buffer layer, a second lower buffer layer provided between the first lower buffer layer and the topological insulator, and a third lower buffer layer provided between the second lower buffer layer and the topological insulator.

The Josephson junction device may further include an upper buffer layer provided between the topological insulator and the second superconducting electrode.

The upper buffer layer may include a first upper buffer layer, a second upper buffer layer between the first upper buffer layer and the second superconducting electrode, and a third upper buffer layer between the second upper buffer layer and the second superconducting electrode.

The Josephson junction device may further include lower nano particles between the third lower buffer layer and the topological insulator and upper nano particles between the first upper buffer layer and the topological insulator.

### BRIEF DESCRIPTION OF THE DRAWINGS

The above and other objects and features of the present disclosure will become apparent by describing in detail embodiments thereof with reference to the accompanying drawings.

FIG. 1 is a perspective view illustrating a Josephson junction device according to an embodiment of the present disclosure.

FIG. 2 is a perspective view illustrating a Josephson junction device according to an embodiment of the present disclosure.

FIG. 3 is a perspective view illustrating a Josephson junction device according to an embodiment of the present disclosure.

FIG. 4A is a view illustrating an example of a copper component in each of a first superconducting electrode and a second superconducting electrode of FIG. 3.

FIG. 4B is a graph depicting a calculation result of formation energy of the copper component of FIG. 4A.

FIG. 5 is a perspective view illustrating a Josephson junction device according to an embodiment of the present disclosure.

FIG. 6 is a perspective view illustrating a Josephson junction device according to an embodiment of the present disclosure.

FIG. 7 is a perspective view illustrating a Josephson junction device according to an embodiment of the present disclosure.

FIG. 8 is a perspective view illustrating a Josephson junction device according to an embodiment of the present disclosure.

### DETAILED DESCRIPTION

In order to fully understand the configuration and effect of the present disclosure, embodiments of the present disclosure will be described with reference to the accompanying drawings. However, the present disclosure is not limited to the embodiments disclosed below. Various embodiments of the present disclosure may be implemented, and various changes may be made to the present disclosure. Herein, the embodiments of the present disclosure are provided to provide complete disclosure of the present disclosure and to provide thorough understanding of the present disclosure to those skilled in the art to which the present disclosure pertains.

Throughout the specification, identical reference numerals denote identical components. The embodiments described herein will be described with reference to block diagrams, perspective views, and/or sectional views which are ideal schematic views of the present disclosure. In the drawings, the thicknesses of areas are exaggerated for effective description of technical contents. Accordingly, the areas illustrated in the drawings have schematic properties, and the shapes of the areas illustrated in the drawings illustrate specific forms of areas of devices and are not intended to limit the spirit and scope of the present disclosure. Although various terms are used to describe various components in various embodiments of the present disclosure, these components should not be limited by these terms. These terms are merely used to distinguish one component from another component. The embodiments described and illustrated herein include complementary embodiments thereof.

The terms used herein are only for description of the embodiments and are not intended to limit the present disclosure. As used herein, the singular forms are intended to include the plural forms as well, unless context clearly indicates otherwise. The terms “comprises” and/or “comprising” used herein specify the presence of stated components, but do not preclude the presence or addition of one or more other components.

Hereinafter, embodiments of the present disclosure will be described in detail with reference to the accompanying drawings.

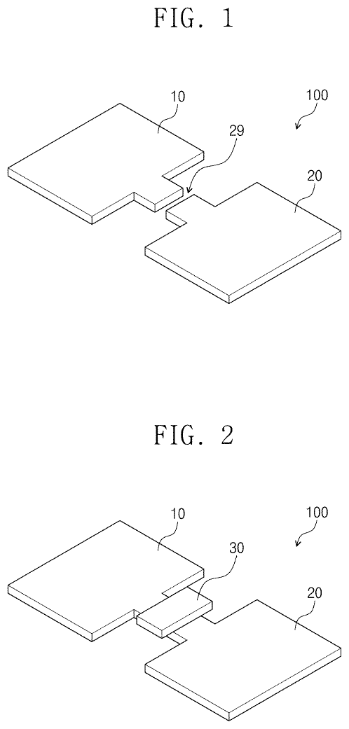

FIG. 1 illustrates a Josephson junction device 100 according to an embodiment of the present disclosure.

Referring to FIG. 1, the Josephson junction device 100 of the present disclosure may include a horizontal Josephson junction device. According to an embodiment, the Josephson junction device 100 of the present disclosure may include a first superconducting electrode 10 and a second superconducting electrode 20.

The first superconducting electrode 10 may be provided on one side of the second superconducting electrode 20. The first superconducting electrode 10 may be separated or spaced apart from the second superconducting electrode 20. The first superconducting electrode 10 may have the shape of “T” when viewed in a plan view. For example, the first superconducting electrode 10 may include CuₓBi₂Se₃. x may be greater than or equal to 0.05 and less than or equal to 0.5 (0.05≤x≤0.5). CuₓBi₂Se₃ may be a topological superconducting material having both topological insulator properties and superconducting properties. The first superconducting electrode 10 having topological superconducting CuₓBi₂Se₃ characteristics may have a two-dimensional structure. The first superconducting electrode 10 may have a thickness of about 5 nm to about 1 μm.

The second superconducting electrode 20 may have a shape and a thickness similar to the shape and the thickness of the first superconducting electrode 10. The second superconducting electrode 20 may have the shape of “T”. The second superconducting electrode 20 may include the same material as the first superconducting electrode 10. The second superconducting electrode 20 may include CuₓBi₂Se₃. x may be greater than or equal to 0.05 and less than or equal to 0.5 (0.05≤x≤0.5). The second superconducting electrode 20 may have a two-dimensional structure. The second superconducting electrode 20 may have a thickness of about 5 nm to about 1 μm.

An air gap 29 may be provided between the first superconducting electrode 10 and the second superconducting electrode 20. Air may be present in the air gap 29. The air gap 29 may function or be used as an insulator between the first superconducting electrode 10 and the second superconducting electrode 20. The first superconducting electrode 10 and the second superconducting electrode 20 may have a distance of about 1 nm to about 900 nm therebetween.

Accordingly, the Josephson junction device 100 of the present disclosure may increase the operating temperature of a superconducting transmon qubit to a temperature of several K to several tens of K using the first superconducting electrode 10 and the second superconducting electrode 20 that contain a copper (Cu) component.

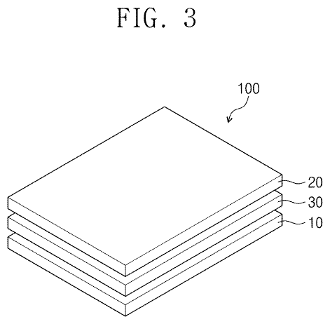

FIG. 2 illustrates a Josephson junction device 100 according to an embodiment of the present disclosure.

Referring to FIG. 2, the Josephson junction device 100 of the present disclosure may further include a topological insulator 30 between a first superconducting electrode 10 and a second superconducting electrode 20. The topological insulator 30 may include a bismuth (Bi)-series chalcogen based material. For example, the topological insulator 30 may include Bi₂Se₃. The topological insulator 30 may have a two-dimensional structure. Alternatively, the topological insulator 30 may include Bi₂Te₃, BiS_{b}, Sb₂Te₃, or TiBiSe₂, but the present disclosure is not limited thereto. The topological insulator 30 may have a thickness of about 1 nm to about 200 nm. The topological insulator 30 may show variations of various physical properties, such as band gap, Fermi level, and Dirac surface state, depending on its structure, composition, doping concentration, and thin film thickness. The topological insulator 30 may have conductivity due to a topological order by causing a band inversion phenomenon by a strong spin-orbit coupling phenomenon on the surface in contact with the first superconducting electrode 10. The topological insulator 30 may have insulating properties therein. The Josephson effect may occur at the junction of the first superconducting electrode 10 including a high-temperature superconductor and the topological insulator 30 so that a superconducting current may flow without an external voltage, and the surface state of the topological insulator 30 may have a unique influence on the characteristics of the Josephson current. In addition, Majorana fermion particles may be generated by a proximity effect at the junction of the first superconducting electrode 10 and the topological insulator 30. The Majorana fermion particles may have the same properties as their antiparticles. In storing and processing information, the Majorana fermion particles may have a property of being very robust to errors and thus may be used as qubits in quantum computing.

Accordingly, the Josephson junction device 100 of the present disclosure may increase the operating temperature of a superconducting transmon qubit to a temperature of several K to several tens of K and may increase the coherence time, by using the first superconducting electrode 10 and the second superconducting electrode 20, which include a high-temperature superconductor, and the topological insulator 30 between the first superconducting electrode 10 and the second superconducting electrode 20.

Meanwhile, the first superconducting electrode 10, the topological insulator 30, and the second superconducting electrode 20 may include Bi₂Se₃ and may eliminate or exclude an interfacial reaction occurring during the formation of hetero junction and defect characteristics of the insulator. In addition, the first superconducting electrode 10, the topological insulator 30, and the second superconducting electrode 20 may achieve simplification of a manufacturing process and a reduction in cost by using a topological superconducting single thin film of Bi₂Se₃. Additionally, the first superconducting electrode 10 and the second superconducting electrode 20 may further include a transition metal provided by ion implantation, diffusion, and laser annealing. The transition metal may include copper (Cu). Alternatively, the transition metal may further include zinc (Zn), nickel (Ni), or niobium (Nb), but the present disclosure is not limited thereto.

Although not illustrated, the first superconducting electrode 10, the topological insulator 30, and the second superconducting electrode 20 may be formed at once through a deposition process of Bi₂Se₃, a photolithography process, and an etching process. Thereafter, the transition metal may be provided in the first superconducting electrode 10 and the second superconducting electrode 20 by a subsequent process of the ion implantation, the diffusion, or the annealing. The first superconducting electrode 10, the topological insulator 30, and the second superconducting electrode 20 may have the same thickness and may be arranged in one direction.

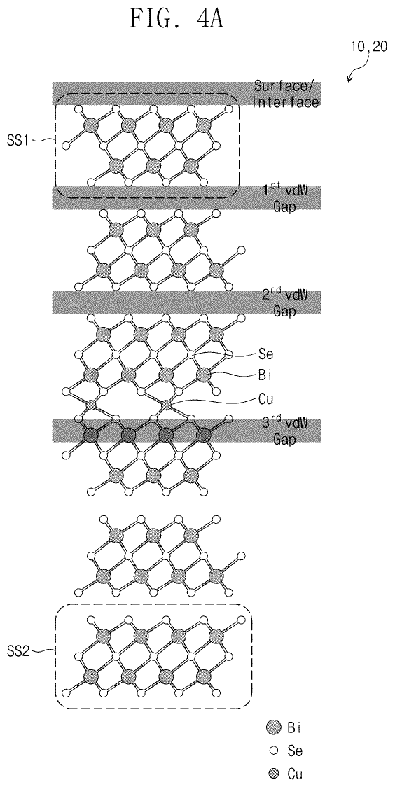

FIG. 3 illustrates a Josephson junction device 100 according to an embodiment of the present disclosure.

Referring to FIG. 3, the Josephson junction device 100 of the present disclosure may include a vertical Josephson junction device. A first superconducting electrode 10, a topological insulator 30, and a second superconducting electrode 20 may have a stack structure. The first superconducting electrode 10, the topological insulator 30, and the second superconducting electrode 20 may be sequentially formed by an in-situ deposition method. For example, the first superconducting electrode 10, the topological insulator 30, and the second superconducting electrode 20 may each be formed by thermal evaporation, molecular beam evaporation, a molecular beam epitaxy deposition method, or a sputtering method.

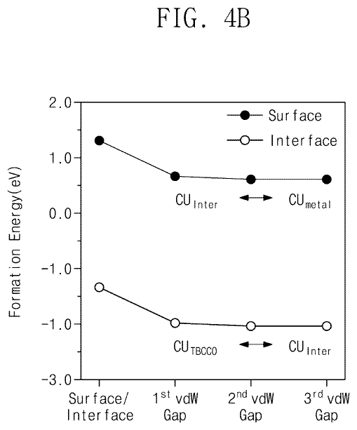

FIG. 4A illustrates an example of a copper (Cu) component in each of the first superconducting electrode 10 and the second superconducting electrode 20 of FIG. 3. FIG. 4B illustrates a calculation result of formation energy of the copper (Cu) component of FIG. 4A.

Referring to FIGS. 4A and 4B, the copper (Cu) component may be provided in Van Der Waals gaps between an upper surface SS1 and a lower surface SS2 of each of the first superconducting electrode 10 and the second superconducting electrode 20 and may have stable formation energy based on the calculation result of the formation energy. The formation energy of the copper (Cu) component may be lower in the Van Der Waals gaps within the bulk than on the surface or interface of each of the first superconducting electrode 10 and the second superconducting electrode 20. Each of the first superconducting electrode 10 and the second superconducting electrode 20 may have first to fifth Van Der Waals gaps. For example, the copper (Cu) component may be provided between the second Van Der Waals gap and the third Van Der Waals gap between the upper surface SS1 and the lower surface SS2. The upper surface SS1 of each of the first superconducting electrode 10 and the second superconducting electrode 20 may be defined between the surface and the first Van Der Waals gap or between the interface and the first Van Der Waals gap. The lower surface SS2 of each of the first superconducting electrode 10 and the second superconducting electrode 20 may be defined under the third Van Der Waals gap. Although not illustrated, the lower surface SS2 may be defined under the fifth Van Der Walls gap.

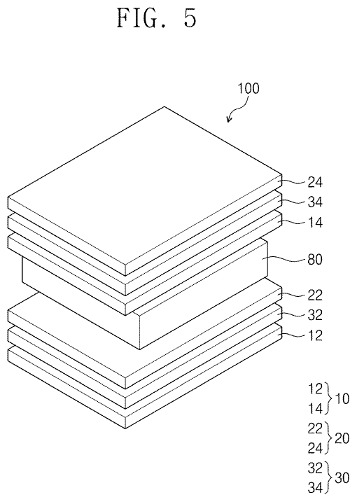

FIG. 5 illustrates a Josephson junction device 100 according to an embodiment of the present disclosure.

Referring to FIG. 5, the Josephson junction device 100 of the present disclosure may include a stack structure of a plurality of first superconducting electrodes 10, a plurality of topological insulators 30, and a plurality of second superconducting electrodes 20 separated by a device insulator 80.

According to an embodiment, the first superconducting electrodes 10 may include a first lower superconducting electrode 12 and a first upper superconducting electrode 14. The first lower superconducting electrode 12 may be provided under the first upper superconducting electrode 14, the device insulator 80, and one of the topological insulators 30. The first upper superconducting electrode 14 may be provided over the device insulator 80. Each of the first lower superconducting electrode 12 and the first upper superconducting electrode 14 may include CuₓBi₂Se₃. x may be greater than or equal to 0.05 and less than or equal to 0.5 (0.05≤x≤0.5).

According to an embodiment, the second superconducting electrodes 20 may include a second lower superconducting electrode 22 and a second upper superconducting electrode 24. The second lower superconducting electrode 22 may be provided between the first lower superconducting electrode 12 and the device insulator 80. The second upper superconducting electrode 24 may be provided over the first upper superconducting electrode 14. Each of the second lower superconducting electrode 22 and the second upper superconducting electrode 24 may include CuₓBi₂Se₃. x may be greater than or equal to 0.05 and less than or equal to 0.5 (0.05≤x≤0.5).

The topological insulators 30 may include a lower topological insulator 32 and an upper topological insulator 34. The lower topological insulator 32 may be provided between the first lower superconducting electrode 12 and the second lower superconducting electrode 22. The upper topological insulator 34 may be provided between the first upper superconducting electrode 14 and the second upper superconducting electrode 24. Each of the lower topological insulator 32 and the upper topological insulator 34 may include Bi₂Se₃. Alternatively, each of the lower topological insulator 32 and the upper topological insulator 34 may include Bi₂Te₃, BiS_{b}, Sb₂Te₃, or TiBiSe₂, but the present disclosure is not limited thereto.

The device insulator 80 may be provided between the second lower superconducting electrode 22 and the first upper superconducting electrode 14. The device insulator 80 may insulate the second lower superconducting electrode 22 from the first upper superconducting electrode 14. The device insulator 80 may include a material similar to the materials of the first lower superconducting electrode 12 and the first upper superconducting electrode 14. The device insulator 80 may include copper (Cu). The device insulator 80 may include the same material as the first superconducting electrodes 10 and the second superconducting electrodes 20. The device insulator 80 may have an advantage that the device is easily manufactured depending on the content of copper (Cu). When the content of copper (Cu) increases, the device insulator 80 may have an amorphous structure rather than a two-dimensional structure. The device insulator 80 may include Cu_{y}Bi₂Se₃. y may be greater than 0.5 and less than or equal to 1 (0.5<y≤1).

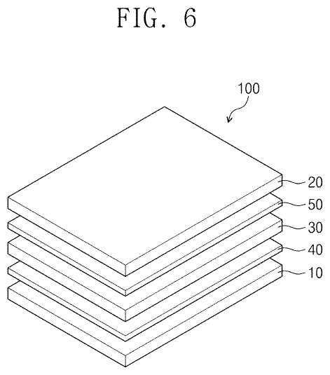

FIG. 6 illustrates a Josephson junction device 100 according to an embodiment of the present disclosure.

Referring to FIG. 6, the Josephson junction device 100 of the present disclosure may further include a lower buffer layer 40 and an upper buffer layer 50. A first superconducting electrode 10, a topological insulator 30, and a second superconducting electrode 20 may be configured in the same manner as in FIG. 3.

The lower buffer layer 40 may be provided between the first superconducting electrode 10 and the topological insulator 30. The lower buffer layer 40 may include at least one of the compositions of the first superconducting electrode 10. For example, the lower buffer layer 40 may include copper (Cu). Alternatively, the lower buffer layer 40 may include antimony (Sb) or tellenium (Te). The lower buffer layer 40 may have a thickness of about 0.5 nm to about 1.5 nm. Additionally, the lower buffer layer 40 may include aluminum oxide (Al₂O₃) or hafnium oxide (HfO₂). The lower buffer layer 40 may be formed by thermal evaporation, molecular beam evaporation, or sputtering. The lower buffer layer 40 may be formed at a deposition rate of about 0.2 Å/sec. The lower buffer layer 40 may increase the deposition efficiency and adhesion of the topological insulator 30.

The lower buffer layer 40 may decrease the surface roughness of the first superconducting electrode 10 to form the topological insulator 30 into a crystal. The device insulator 30 may include Bi₂Se₃ in a crystalline state. Bi₂Se₃ in the crystalline state may enhance the Josephson effect.

The upper buffer layer 50 may be provided between the topological insulator 30 and the second superconducting electrode 20. The upper buffer layer 50 may have the same material as the lower buffer layer 40. For example, the upper buffer layer 50 may include copper (Cu), antimony (Sb), or tellenium (Te). The upper buffer layer 50 may have a thickness of about 0.5 nm to about 1.5 nm.

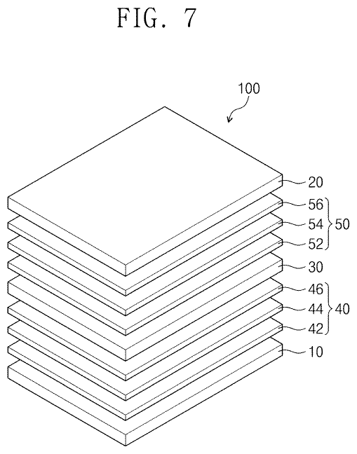

FIG. 7 illustrates a Josephson junction device 100 according to an embodiment of the present disclosure.

Referring to FIG. 7, the Josephson junction device 100 of the present disclosure may include a plurality of lower buffer layers 40 and a plurality of upper buffer layers 50. A first superconducting electrode 10, a topological insulator 30, and a second superconducting electrode 20 may be configured in the same manner as in FIG. 4.

The lower buffer layers 40 may decrease the surface roughness of the first superconducting electrode 10 and may prevent diffusion of copper oxide within the first superconducting electrode 10. According to an embodiment, the lower buffer layers 40 may include a first lower buffer layer 42, a second lower buffer layer 44, and a third lower buffer layer 46. The first lower buffer layer 42 may be provided between the first superconducting electrode 10 and the topological insulator 30. The first lower buffer layer 42 may decrease the surface roughness of the first superconducting electrode 10. For example, the first lower buffer layer 42 may include copper (Cu), antimony (Sb), or tellenium (Te). The second lower buffer layer 44 may be provided between the first lower buffer layer 42 and the topological insulator 30. The second lower buffer layer 44 may decrease or prevent diffusion of copper oxide within the topological insulator 30. For example, the second lower buffer layer 44 may include graphene. The third lower buffer layer 46 may be provided between the second lower buffer layer 44 and the topological insulator 30. The third lower buffer layer 46 may maximally decrease the surface roughness of the second lower buffer layer 44 and may increase the insulation properties of the topological insulator 30. For example, the third lower buffer layer 46 may include silicon carbide (SiC).

The upper buffer layers 50 may prevent diffusion of copper oxide within the second superconducting electrode 20. According to an embodiment, the upper buffer layers 50 may include a first upper buffer layer 52, a second upper buffer layer 54, and a third upper buffer layer 56. The first upper buffer layer 52 may be provided between the topological insulator 30 and the second superconducting electrode 20. The first upper buffer layer 52 may increase the insulation properties of the topological insulator 30. For example, the first upper buffer layer 52 may include silicon carbide (SiC). The second upper buffer layer 54 may be provided between the first upper buffer layer 52 and the second superconducting electrode 20. The second upper buffer layer 54 may decrease or prevent diffusion of a copper component of the second superconducting electrode 20. For example, the second upper buffer layer 54 may include graphene. The third upper buffer layer 56 may be provided between the second upper buffer layer 54 and the second superconducting electrode 20. The third upper buffer layer 56 may decrease a difference in surface roughness between the second superconducting electrode 20 and the topological insulator 30. For example, the third upper buffer layer 56 may include copper (Cu), antimony (Sb), or tellenium (Te).

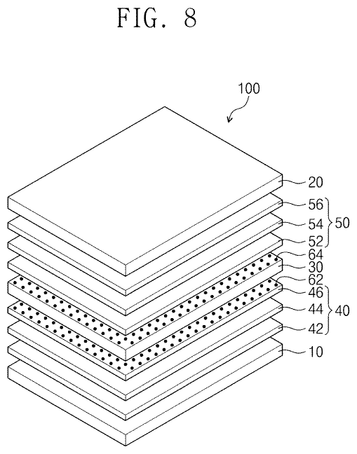

FIG. 8 illustrates a Josephson junction device 100 according to an embodiment of the present disclosure.

Referring to FIG. 8, the Josephson junction device 100 of the present disclosure may further include lower nano particles 62 and upper nano particles 64. A first superconducting electrode 10, a topological insulator 30, a second superconducting electrode 20, a lower buffer layer 40, and an upper buffer layer 50 may be configured in the same manner as in FIG. 6.

The lower nano particles 62 may be provided between a third lower buffer layer 46 and the topological insulator 30. The lower nano particles 62 may increase the electrical properties of the third lower buffer layer 46 and the topological insulator 30 and may increase the adhesion of the third lower buffer layer 46 and the topological insulator 30. For example, the lower nano particles 62 may include a metal such as gold (Au), silver (Ag), aluminum (Al), tungsten (W), or platinum (Pt).

The upper nano particles 64 may be provided between the topological insulator 30 and a first upper buffer layer 52. The upper nano particles 64 may increase the electrical properties of the topological insulator 30 and the first upper buffer layer 52 and may increase the adhesion of the topological insulator 30 and the first upper buffer layer 52. The upper nano particles 64 may have the same material as the lower nano particles 62. For example, the upper nano particles 64 may include a metal such as gold (Au), silver (Ag), aluminum (Al), tungsten (W), or platinum (Pt).

The Josephson junction devices according to the embodiments of the present disclosure may increase the operating temperature of the superconducting transmon qubit and the coherence time using the first and second superconducting electrodes including CuₓBi₂Se₃ and the topological insulator between the first and second superconducting electrodes.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A Josephson junction device comprising:
a first superconducting electrode; and
a second superconducting electrode spaced apart from the first superconducting electrode,
wherein each of the first superconducting electrode and the second superconducting electrode includes CuₓBi₂Se₃, and
wherein x is greater than or equal to 0.05 and less than or equal to 0.5 (0.05≤x≤0.5).

2. The Josephson junction device of claim 1, further comprising:
a topological insulator provided between the first superconducting electrode and the second superconducting electrode.

3. The Josephson junction device of claim 2, wherein the topological insulator includes Bi₂Se₃.

4. The Josephson junction device of claim 2, wherein the first superconducting electrode includes a plurality of first superconducting electrodes, and the second superconducting electrode includes a plurality of second superconducting electrodes,
wherein the plurality of first superconducting electrodes include:
a first lower electrode; and
a first upper electrode over the first lower electrode, and
wherein the plurality of second superconducting electrodes include:
a second lower electrode between the first lower electrode and the first upper electrode; and
a second upper electrode over the first upper electrode.

5. The Josephson junction device of claim 4, wherein the topological insulator includes a plurality of topological insulators, and
wherein the plurality of topological insulators include:
a lower topological insulator between the first lower electrode and the second lower electrode; and
an upper topological insulator between the first upper electrode and the second upper electrode.

6. The Josephson junction device of claim 5, further comprising:
a device insulator between the second lower electrode and the first upper electrode.

7. The Josephson junction device of claim 6, wherein the device insulator includes Cu_{y}Bi₂Se₃, and
wherein y is greater than 0.5 and less than or equal to 1 (0.5<y≤1).

8. The Josephson junction device of claim 2, further comprising:
a lower buffer layer between the first superconducting electrode and the topological insulator; and
an upper buffer layer provided between the topological insulator and the second superconducting electrode.

9. The Josephson junction device of claim 8, wherein the lower buffer layer includes:
a first lower buffer layer;
a second lower buffer layer between the first lower buffer layer and the topological insulator;
a third lower buffer layer between the second lower buffer layer and the topological insulator; and
lower nano particles between the third lower buffer layer and the topological insulator.

10. The Josephson junction device of claim 8, wherein the upper buffer layer includes:
a first upper buffer layer;
a second upper buffer layer between the first upper buffer layer and the second superconducting electrode;
a third upper buffer layer between the second upper buffer layer and the second superconducting electrode; and
upper nano particles between the first upper buffer layer and the topological insulator.

11. A Josephson junction device comprising:
a first lower electrode;
a lower topological insulator provided on the first lower electrode;
a second lower electrode provided on the lower topological insulator;
a device insulator provided on the second lower electrode;
a first upper electrode provided on the device insulator;
an upper topological insulator provided on the first upper electrode; and
a second upper electrode provided on the upper topological insulator.

12. The Josephson junction device of claim 11, wherein each of the first lower electrode, the second lower electrode, the first upper electrode, and the second upper electrode includes CuₓBi₂Se₃, and
wherein x is greater than or equal to 0.05 and less than or equal to 0.5 (0.05≤ x≤0.5).

13. The Josephson junction device of claim 11, wherein the device insulator includes Cu_{y}Bi₂Se₃, and
wherein y is greater than 0.5 and less than or equal to 1 (0.5<y≤1).

14. The Josephson junction device of claim 11, wherein each of the lower topological insulator and the upper topological insulator includes Bi₂Se₃.

15. The Josephson junction device of claim 11, wherein each of the lower topological insulator and the upper topological insulator includes Bi₂Te₃, BiS_{b}, Sb₂Te₃, or TiBiSe₂.

16. A Josephson junction device comprising:
a first superconducting electrode;
a topological insulator provided on the first superconducting electrode;
a second superconducting electrode provided on the topological insulator; and
a lower buffer layer provided between the first superconducting electrode and the topological insulator.

17. The Josephson junction device of claim 16, wherein the lower buffer layer includes:
a first lower buffer layer;
a second lower buffer layer provided between the first lower buffer layer and the topological insulator; and
a third lower buffer layer provided between the second lower buffer layer and the topological insulator.

18. The Josephson junction device of claim 17, further comprising:
an upper buffer layer provided between the topological insulator and the second superconducting electrode.

19. The Josephson junction device of claim 18, wherein the upper buffer layer includes:
a first upper buffer layer;
a second upper buffer layer between the first upper buffer layer and the second superconducting electrode; and
a third upper buffer layer between the second upper buffer layer and the second superconducting electrode.

20. The Josephson junction device of claim 19, further comprising:
lower nano particles between the third lower buffer layer and the topological insulator; and
upper nano particles between the first upper buffer layer and the topological insulator.
